(19) United States
(12) Patent Application Publication
(10) Pub. No.: US 2025/0112057 A1
(43) Pub. Date: Apr. 3, 2025

(54) CHEMICAL ETCHING OF MOLYBDENUM FILMS

(71) Applicant: ASM IP Holding B.V., Almere (NL)

(72) Inventors: Patricio Eduardo Romero, Wilsele (BE); Charles Dezelah, Helsinki (FI); Daniele Piumi, Etterbeek (BE)

(21) Appl. No.: 18/898,455

(22) Filed: Sep. 26, 2024

Related U.S. Application Data
(60) Provisional application No. 63/586,098, filed on Sep. 28, 2023.

(51) Int. Cl. H01L 21/3213; C09K 13/08; H01L 21/67

(52) U.S. Cl. CPC H01L 21/32138; C09K 13/08; H01L 21/67069

(57) ABSTRACT

The present disclosure relates to methods for etching a molybdenum (Mo) film and systems for performing said method. The disclosed methods comprise, exposing a substrate comprising an Mo outer layer to an oxygen containing reactant to convert at least a portion of the Mo outer layer to molybdenum oxide (MoOₓ), then exposing the substrate to an etchant that comprises one or more S—X bond(s), P—X bond(s), and Si—X bond(s), where X is Cl or Br, to convert the molybdenum oxide to a volatile Mo containing compound that is removed from the surface of the substrate, thereby reducing the thickness of the Mo outer layer.

### CROSS-REFERENCE TO RELATED APPLICATION(S)

This Application claims the benefit of U.S. Provisional Application 63/586,098 filed on Sep. 28, 2023, the entire contents of which are incorporated herein by reference.

### FIELD

The present disclosure relates to methods and systems for etching molybdenum films and using said methods and systems in semiconductor device manufacturing.

### BACKGROUND

Molybdenum is a metal candidate for several applications in next generation semiconductor devices. For instance, molybdenum is a potential core metal replacement for local interconnects in logic devices. Compared to copper, the incumbent metal, molybdenum has a lower resistivity (ρ) and therefore its use may enable narrower, more closely spaced interconnects that do not require a barrier layer. Molybdenum is also a potential replacement metal in future 3D NAND and 3D DRAM memory devices. For example, compared to tungsten, the incumbent metal in 3D NAND devices, molybdenum has a lower resistivity (ρ) and a higher work function which may enable thinner, longer word lines with a larger effective barrier to delay the onset of electron injection from the gate during the erase operation. In order to enable the manufacture of such next generation devices at high volume, improved deposition and etch methods for molybdenum are required.

Atomic layer etching (ALE) is a method that allows for uniform and precise nanoscale removal of material from the surface of a film. ALE is typically achieved by functionalizing a surface to increase its chemical reactivity, followed by a removal step of the functionalized layer. Molybdenum ALE methods are known and generally rely on the use of a plasma for one or both of the functionalization and removal steps. Plasma based methods, however, may be problematic for the formation of ultra-high aspect ratios features, such as those required for future 3D NAND and 3D DRAM structures, due to the recombination of radicals that are formed in the plasma; thus, thermal ALE methods are preferred. Thermal ALE methods for molybdenum have been reported; however, they are unnecessarily complex, requiring multiple etch steps per ALE cycle. Further innovation in methods for etching molybdenum is needed to enable its use in high aspect ratio structures and in high volume manufacturing. The present disclosure addresses and meets these needs.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure relates to methods for etching a molybdenum containing film. The methods comprise: providing a substrate comprising a molybdenum containing film in a reaction space and exposing the substrate to a first etchant to convert at least a portion of the molybdenum containing film to a volatile Mo containing compound, thereby reducing a thickness of the molybdenum containing film. In some embodiments, the molybdenum containing film comprises an outer region or layer positioned over a bulk region, wherein the outer region or layer comprises molybdenum oxide (MoOₓ) and the bulk region comprises metallic molybdenum. At least a portion of the outer region or layer is converted to the volatile Mo containing compound.

Additionally, other aspect of the present disclosure relates to methods for etching molybdenum (Mo) from a surface of a substrate. The methods comprise providing a substrate comprising an Mo outer layer having an initial thickness in a reaction space and performing a cyclic etch process. The cyclic etch process comprises: exposing the substrate to an oxygen containing reactant to convert at least a portion of the Mo outer layer to molybdenum oxide (MoOₓ); purging the reaction space; exposing the substrate to a first etchant to convert the MoOₓ to a volatile Mo containing compound, wherein the first etchant comprises one or more of S—X bond(s), P—X bond(s), and Si—X bond(s), where X is Cl or Br; and purging the reaction space. The cyclic etch process may be repeated to reduce the initial thickness of the Mo outer layer to a final thickness or to remove the Mo outer layer from the substrate.

In some embodiments, the cyclic etch process further comprises, exposing the substrate to a second etchant to remove a non-Mo oxide layer from the surface of the substrate and purging the reaction space after exposing the substrate to the second etchant.

In some embodiments, the methods further comprise performing a continuous etch step prior to the cyclic etch process, wherein the continuous etch step comprises exposing the substrate to a continuous etchant. In some embodiments, the continuous etch step comprises exposing the substrate to a continuous etchant and purging the reaction space after the exposing the substrate to a continuous etchant.

In some embodiments, the methods further comprise maintaining a temperature of the substrate at a set temperature.

Another aspect of the present disclosure relates to systems, such as, for example, a semiconductor apparatus, for etching molybdenum (Mo) from a surface of a substrate. The systems comprise: a reaction space for accommodating a substrate comprising an Mo outer layer having an initial thickness; a first source for providing an oxygen containing reactant in gas communication via a first valve with the reaction space; a second source for providing a first etchant in gas communication via a second valve with the reaction space, wherein the first etchant comprises one or more of S—X bond(s), P—X bond(s), and Si—X bond(s), where X is Cl or Br; and a controller operably connected to the first valve and the second valve. The controller is configured and programmed to perform a cyclic etch process comprising sequentially: opening the first valve to the first source to supply the oxygen containing reactant into the reaction space, wherein the oxygen containing reactant converts at least a portion of the Mo outer layer to molybdenum oxide (MoOₓ); closing the first valve to the first source to cease the supply the oxygen containing reactant into the reaction space; opening the second valve to the second source to supply the first etchant into the reaction space, wherein the first etchant converts the MoOₓ to a volatile Mo containing compound; and closing the second valve to the second source to cease the supply of the first etchant into the reaction space. The controller may be further programed to sequentially repeat the opening of the first valve to the first source, the closing of the first valve to the first source, the opening of the second valve to the second source, and the closing of the second valve to the second source to reduce the initial thickness of the Mo outer layer to a final thickness or to remove the Mo outer layer from the substrate.

In some embodiments, the systems further comprise a third source for providing a second etchant in gas communication via a third valve with the reaction space and the controller is further operably connected to the third valve and configured and programmed to control: opening the third valve to the third source to supply the second etchant into the reaction space, wherein the second etchant removes a non-Mo oxide layer from the substrate; and closing the third valve to the third source. In some embodiments, the controller may be further programed to, after each of the closing of the second valve to the second source, open the third valve to the third source and close the third valve to the third source.

In some embodiments, the system is further configured to provide a continuous etchant to the reaction space, prior to performing the cyclic etch process. In some embodiments, the controller may be further programed to, prior to the opening the first valve to the first source, open the second valve to the second source and close the second valve to the second source. In other embodiments, the systems further comprise a fourth source for providing a continuous etchant in gas communication via a fourth valve with the reaction space and the controller is further operably connected to the fourth valve and configured and programmed to control: opening the fourth valve to the fourth source to supply the continuous etchant into the reaction space; and closing the fourth valve to the fourth source to cease the flow of the continuous etchant into the reaction space. In some embodiments, the controller may be further programed to, prior to the opening the first valve to the first source, open the fourth valve to the fourth source and close the fourth valve to the fourth source.

In some embodiments, the systems further comprise at least one heating element in thermal communication with the substrate and the controller is further operably connected to the at least one heating element and configured and programmed to control a temperature of the at least one heating element to maintain a temperature of the substrate at a set temperature.

In these aspects, in some embodiments, the oxygen containing reactant is selected from the group consisting of oxygen (O₂), ozone (O₃), water (H₂O), hydrogen peroxide (H₂O₂), an organic peroxide, an alcohol, nitrogen dioxide (NO₂), nitrous oxide (N₂O), nitric oxide (NO), dinitrogen pentoxide (N₂O₅), pyridine oxide (C₅H₅NO), an amine oxide, and combinations thereof. In some embodiments, the oxygen containing reactant is selected from the group consisting of oxygen (O₂), ozone (O₃), nitrous oxide (N₂O), and combinations thereof.

In these aspects, in some embodiments, the first etchant is selected from the group consisting of thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof. In some embodiments, the first etchant is selected from the group consisting of SOCl₂, PCl₃, PCl₅, SiCl₄, and combinations thereof. In some embodiments, the first etchant is SOCl₂.

In these aspects, in some embodiments, the oxygen containing reactant is selected from the group consisting of oxygen (O₂), ozone (O₃), nitrous oxide (N₂O), and combinations thereof and the first etchant is selected from the group consisting of SOCl₂, PCl₃, PCl₅, SiCl₄, and combinations thereof. In some embodiments, the oxygen containing reactant is selected from the group consisting of oxygen (O₂), ozone (O₃), nitrous oxide (N₂O), and combinations thereof and the first etchant is SOCl₂. In some embodiments, the oxygen containing reactant comprises oxygen (O₂) and the first etchant comprises SOCl₂. In some embodiments, the oxygen containing reactant comprises nitrous oxide (N₂O) and the first etchant comprises SOCl₂.

In these aspects, in some embodiments, the volatile Mo containing compound is a molybdenum oxychloride or a molybdenum oxybromide. In some embodiments, the volatile Mo containing compound is a molybdenum oxychloride.

In these aspects, in some embodiments, the substrate is maintained at a temperature from at least about 300° C. to no more than about 600° C. In some embodiments, the substrate is maintained at a temperature of less than about 450° C. In some embodiments, the substrate is maintained at a temperature of less than about 425° C. In some embodiments, the substrate is maintained at a temperature of less than about 400° C.

In these aspects, in some embodiments, the cyclic etch process is performed under thermal conditions in a plasma-free environment.

In these aspects, in some embodiments, the continuous etchant is selected from the group consisting of molybdenum pentachloride (MoCl₅), thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof. In some embodiments, the continuous etchant is selected from the group consisting of molybdenum pentachloride (MoCl₅), thionyl chloride (SOCl₂), phosphorus pentachloride (PCl₅), phosphorus trichloride (PCl₃), silicon tetrachloride (SiCl₄), and combinations thereof. In some embodiments, the continuous etchant is thionyl chloride (SOCl₂). In some embodiments, the continuous etchant is molybdenum pentachloride (MoCl₅). In some embodiments, the continuous etchant is the same chemical compound as the first etchant.

In these aspects, in some embodiments, the substrate is maintained at a first temperature during the continuous etch step and a second temperature during the cyclic etch process. In some embodiments, the first temperature is greater than the second temperature. In other embodiments, the first temperature is less than the second temperature.

In these aspects, in some embodiments, the substrate comprises at least one stacked structure comprising a top portion and sidewalls formed from a plurality of stacked alternating materials layers and an Mo outer layer that is position on the sidewalls of the stacked structure(s). In some embodiments, the substrate comprises at least one intermediate 3D NAND stacked structure or at least one intermediate 3D DRAM stacked structure. In some embodiments, the Mo outer layer is positioned on at least one sidewall of the at least one intermediate 3D NAND stacked structure or the at least one intermediate 3D DRAM stacked structure.

In these aspects, in some embodiments, the reaction space comprises one or more reaction chambers of a semiconductor processing apparatus.

These and other embodiments will become readily apparent to those skilled in the art from the following detailed description of certain embodiments having reference to the attached figures. The invention is not being limited to any particular embodiments disclosed.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. The illustrations presented herein are not meant to be actual views of any particular material, structure, or device, but are merely idealized representations or pictorial representations that are used to describe embodiments of the disclosure. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1 is a process flow diagram of an exemplary embodiment of a cyclic etch process disclosed herein. Optional steps are shown by the dashed lines.

FIG. 2 is a process flow diagram of an exemplary embodiment of a cyclic etch process disclosed herein. Optional steps are shown by the dashed lines.

FIG. 3 is a pictorial representation of an embodiment of an etch sequence disclosed herein, where the etchant is SOCl₂.

FIG. 4 is a pictorial representation of an embodiment of an etch sequence disclosed herein, where the etchant is PCl₅.

FIG. 5 is a pictorial representation of an embodiment of an etch sequence disclosed herein, where the etchant is SiCl₄.

FIG. 6 is a process flow diagram of an exemplary embodiment of the disclosure, wherein a continuous etch step is performed prior to a cyclic etch process. Optional steps are shown by the dashed lines.

FIG. 7 is a process flow diagram of an exemplary embodiment of the disclosure, wherein a continuous etch step is performed prior to a cyclic etch process. Optional steps are shown by the dashed lines.

FIG. 8 is a schematic presentation of a semiconductor processing apparatus according to an embodiment of the present disclosure.

FIG. 9A, FIG. 9B, and FIG. 9C are pictorial representations of an exemplary intermediate structure for forming an interconnect at various stages of fabrication.

FIG. 10A, FIG. 10B, and FIG. 10C are pictorial representations of an exemplary intermediate 3D NAND stacked structure at various stages of fabrication.

FIG. 11A, FIG. 11B, and FIG. 11C are pictorial representations of an exemplary intermediate 3D DRAM stacked structure at various stages of fabrication.

### DETAILED DESCRIPTION

The description of embodiments of methods, systems, and structures provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separate from each other. The headings provided herein, if any, are for convenience only and do not necessarily affect the scope or meaning of the claimed invention.

### Definitions

As used herein, an “alkyl group” refers a functional group that can be derived from an alkane (e.g., an alkane less a hydrogen atom). An alkyl group may have a linear, branched, or cyclic structure. Generally, an alkyl group is a part of a larger molecule, and the symbol “R” may be used to designate a generic unspecified alkyl group. In cases where a molecule has more than one R group, each R group may be independently selected. In some embodiments of the present disclosure, an alkyl group refers to a linear or branched C₁ to C₆ alkane less one hydrogen atom (i.e., a C₁ to C₆ alkyl group), such as a methyl group (—CH₃), an ethyl group (—CH₂CH₃), an n-propyl group (—CH₂CH₂CH₃), an iso-propyl group (—CH(CH₃)₂), an n-butyl group (—CH₂CH₂CH₂CH₃), an iso-butyl group (—CH₂CH(CH₃)CH₃), a s-butyl group (—CH(CH₃)CH₂CH₃), a t-butyl group (—C(CH₃)₃), an n-pentyl group (—CH₂CH₂CH₂CH₂CH₃), a 2-pentyl group (—CH(CH₃)CH₂CH₂CH₃), a 3-pentyl group (—CH₂CH(CH₃)CH₂CH₃), a neo-pentyl group (—CH₂C(CH₃)₃), a t-pentyl group (—C(CH₃)₂CH₂CH₃), an iso-pentyl group (—CH₂CH₂CH(CH₃)₂), a sec-iso-pentyl group (—C(CH₃)CH(CH₃)₂) and a hexyl group. In some embodiments, an alkyl group refers a methyl group (—CH₃) or an ethyl group (—CH₂CH₃).

As used herein, an “anisotropic process” refers to a process that proceeds at varying rates depending upon the direction over a reaction space. For example, in anisotropic etching, etching may primarily occur in one direction over another direction on a substrate surface. In one such example, etching may primarily occur on the lateral surfaces of the substrate, while not significantly occurring on the sidewalls of recessed portions of a substrate.

As used herein, an “aryl group” refers a functional group or a substituent that is derived from an aromatic ring, usually an aromatic hydrocarbon. Generally, an aryl group is a part of a larger molecule, and the symbol “R” may be used to designate a generic unspecified aryl group. In cases where a molecule has more than one R group, each R group may be independently selected. In some embodiments of the present disclosure, an aryl group refers a phenyl group (—C₆H₅).

As used herein, “atomic layer etching”, abbreviated as “ALE”, is a vapor phase cyclic process for removing thin layers or sub-layers of material from the surface of a substrate using sequential reactions that are conducted in a reaction space (i.e., one or more reaction chambers). Generally, in ALE processes, during each cycle, at least one reactant is introduced into a reaction space comprising a substrate to functionalize or chemically modify the top surface layer(s) of the substrate. Thereafter, an etchant is introduced into the reaction space. The etchant reacts with the functionalized top layer(s) to form volatile products, thereby removing material from the surface of the substrate. Typically, the etching step is self-limiting in that excess etchant does react, or does not substantially react, with the newly exposed, non-functionalized surface. Other reaction steps may be included in the cyclic process as needed, for example, additional functionalization steps or etching steps may be included.

As used herein, “cyclic etch process” refers to the sequential introduction of reactants into a reaction space (i.e., one or more reaction chambers) to etch at least a portion of a target surface and includes processing techniques such as cyclical chemical vapor etch and ALE.

As used herein, an “etchant” refers to a compound that participates in a chemical reaction with a surface to remove material from the surface. The chemical reaction may result in the formation of volatile or gas-phase reaction product(s) that contain a portion of the surface material (e.g., element(s) or group(s) of the surface material).

As used herein, a “film” or “layer”, which may be used interchangeably, refers to a continuous, substantially continuous, or non-continuous material that extends in a direction perpendicular to a thickness direction to cover at least a portion of a surface. A film may be positioned on a lateral surface and/or on a sidewall of recessed features of a surface. A film can include two-dimensional materials, three-dimensional materials, nanoparticles, partial or full molecular layers, partial or full atomic layers, and/or clusters of atoms or molecules. A film may be built up from one or more non-discernable monolayers or sub-monolayers to produce a uniform or a substantially uniform material, wherein the number of monolayers or sub-monolayers influences the thickness of the material.

As used herein, a “gas” refers to a state of mater consisting of atoms and/or molecules that have neither a defined volume nor shape. A gas includes vaporized solid and/or liquid and may be constituted by a single gas or a mixture of gases, depending on the context.

As used herein, an “isotropic process” refers to a process that proceeds at essentially the same rate regardless of the direction. For example, in isotropic etching, etching may occur in multiple directions on a substrate surface, such as, for example, on the lateral surfaces of the substrate and on the sidewalls of recessed portions of a substrate.

As used herein, “molybdenum” or “Mo” refers to metallic molybdenum in zero oxidation state. In some embodiments, Mo may comprise other elements as impurities, such as, for example, hydrogen, oxygen, carbon, nitrogen, and halogens. In some embodiments, molybdenum may have a purity of at least about 90% (by weight), or at least about 95%, or at least about 98%, or at least about 99%, or at least 99.5, or at least about 99.9%.

As used herein, “molybdenum oxide” or “MoOₓ” refers to a material that comprises Mo—O bond(s). Molybdenum oxide can be represented by the formula MoOₓ, where x is a variable that can range from about 1 to about 3, typically from about 2 to about 3. In an MoOₓ film, the variable x may vary across the thickness of the MoOₓ layer, with x being closer to 3 at the surface of the layer compared to the interior portion of the layer. It will be understood that the variable x may vary depending on the specific reactants and process conditions utilized to form the molybdenum oxide, among other factors, and may not be stochiometric. The morphology of MoOₓ may also vary and may be crystalline, with one or more phases, or it may be amorphous depending on the specific reactants and process conditions utilized to form MoOₓ, among other factors.

As used herein, “molybdenum oxyhalide” or “MoOₓX_{y}” refers to a material that comprises Mo—O bond(s) and Mo—X bond(s), where X is a halogen atom selected from chloride (Cl), bromide (Br), or a combination thereof. Molybdenum oxyhalide can be represented by the formula MoOₓX_{y}, where x is a variable that can range from about 1 to about 2 and y is a variable that can range from about 1 to about 4. It will be understood that the variables x and y may vary depending on the specific reactants and process conditions utilized to form the molybdenum oxyhalide, among other factors. In some embodiments of the present disclosure, the molybdenum oxyhalide is a molybdenum oxychloride (MoOₓCl_{y}) such as, for example, molybdenum tetrachloride oxide (MoOCl₄) and/or molybdenum dichloride dioxide (MoO₂Cl₂). In other embodiments, the molybdenum oxyhalide is a molybdenum oxybromide (MoOₓBr_{y}).

As used herein, a “plasma” refers to an ionized gas that comprises roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide different fluxes of the various species.

As used herein, “purge” or “purging” refers to clearing, removing, or replacing of certain gas-phase and volatile species from a reaction space. Purging may be affected, for example, by evacuating the reaction space with a vacuum pump and/or by replacing the gas inside a reaction space with an inert or substantially inert gas such as argon or nitrogen. In some instances, a purge step may be implemented between two pulses of gases which react with each other, or, in other instances, purging may be implemented between two pulses of gases that do not react with each other. Purging may avoid, or at least reduce, gas-phase interactions between two gases reacting with each other. Purging may be used to remove volatile or gas-phase reaction products from the surface of the substrate. It shall be understood that a purging can be affected either in time or in space, or both. For example, in the case of temporal purges, a purge step can be used in the temporal sequence of providing a first reactant to a reaction chamber, providing a purge gas to the reaction chamber, and then providing a second reactant to the reaction chamber, wherein the substrate on which a material is deposited or removed does not move. For example, in the case of spatial purges, a purge step can involve moving a substrate from a first location to which a first reactant is continually supplied, through a purge gas curtain, to a second location to which a second reactant is continually supplied.

As used herein, a “reactant” refers to a compound that participates in a chemical reaction to form another compound or element. In some instances, a reactant is an etchant. In other instances, the compound or element that results from the chemical reaction is not volatile and/or it does not comprise a portion of the surface material (e.g., element(s) or group(s) of the surface material) and therefore the reactant is not an etchant.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

As used herein, “volatile” refers to a substance that readily transitions from a liquid or a solid state to the gas-phase. At a given temperature and pressure, a volatile compound, or a compound with high volatility, is more likely to exist as a vapor; while a nonvolatile compound, or a compound with low volatility, is more likely to be a liquid or solid.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. Comprising, including, and having can be used interchangeably and include the meaning of “consisting of”. The phrase “consisting of”, however, indicates that no other features or components are present other than those mentioned, unless the context clearly indicates otherwise.

The term “about” as applied to a value generally refers to a range of numbers that is considered equivalent to the recited value (e.g., having the same function or result). In some instances, the term “about” may include numbers that are rounded to the nearest significant figure.

The term “essentially” as applied to a composition, a method, or a system generally means that the additional components do not substantially modify the properties and/or function of the composition, the method, or the system.

The terms “on” or “over” may be used to describe a relative location relationship. For example, an element, a film, or a layer may be directly positioned on or over and physically contacting at least a portion another element, film, or layer; or, alternatively, an element, a film, or a layer may be on or over another element, film or layer but have one or more interposed elements, films, or layers therebetween. Therefore, unless the term “directly” is also used, the terms “on” or “over” will be construed to be a relative concept. Similar to this, it will be understood that the terms “under”, “underlying”, or “below” describe a relative location relationship and should be construed to be relative concepts, unless otherwise indicated.

The term “substantially” as applied to a composition, a method, or a system generally refers to a proportion of at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.5, and so on.

The present disclosure generally relates to methods and systems for etching a molybdenum containing film. In this context, a molybdenum containing film is a film that comprises molybdenum and may further comprise additional elements such as oxygen. In some embodiments, the molybdenum containing film comprises a bulk region that primarily comprises metallic molybdenum and an outer region or layer, positioned over the bulk region, that primarily comprises molybdenum oxide (MoOₓ). It has been found that certain etchants can convert molybdenum oxide to a volatile molybdenum containing compound and, under certain process conditions, this reactivity may be exploited to provide for controlled etching of molybdenum containing films. More specifically, the present disclosure generally relates to methods and systems for etching a molybdenum (Mo) film using a cyclic etch process, wherein at least a portion of the molybdenum film is converted to molybdenum oxide which is then reacted with an etchant to form a volatile molybdenum containing compound. In some embodiments, molybdenum etching may beneficially be performed using a simple two-step (i.e., two reactant) process under thermal conditions. The methods and systems for etching molybdenum may be used in a variety of applications in the semiconductor industry, such as, for example, in the manufacture of local interconnects in logic devices and 3D NAND and 3D DRAM structures in memory devices.

An aspect of the present disclosure relates to methods for etching a molybdenum containing film. The methods comprise providing a substrate comprising a molybdenum containing film in a reaction space (i.e., one or more reaction chambers) and exposing the substrate to an etchant to convert at least a portion of the molybdenum containing film to a volatile Mo containing compound. The molybdenum containing film may comprises an outer region or layer that is positioned over a bulk region, wherein the outer layer comprises molybdenum oxide (MoOₓ) and the bulk region comprises metallic molybdenum. At least a portion of the outer layer is converted to the volatile Mo containing compound that is removed from the surface of the substrate, thereby reducing the thickness of the molybdenum containing film.

More specifically, in some embodiments, the methods for etching a molybdenum containing film comprise, providing a substrate comprising a molybdenum (Mo) outer layer having an initial thickness in a reaction space (i.e., one or more reaction chambers) and exposing the substrate to an oxygen containing reactant to convert at least a portion of the Mo outer layer to molybdenum oxide (MoOₓ). Next, the substrate is exposed to an etchant to convert the MoOₓ to a volatile Mo containing compound that is removed from the surface of the substrate, thereby reducing the thickness of the Mo outer layer. In some embodiments, a non-Mo containing oxide layer is formed on the surface of the substrate and the surface is further exposed to a second etchant to remove the non-Mo containing oxide layer. The reaction sequence is self-limiting in that the removal of the volatile Mo containing compound exposes a new outer layer (which may be Mo or another material) that does not react, or does not substantially react, with the etchant under the employed process conditions (e.g., temperatures and pressures). This allows for etching to be performed in a well-defined manner. Mo removal occurs layer-by-layer by repeating the reaction sequence in a cyclic etch processes to remove a targeted thickness of the Mo outer layer from the substrate. Other process steps may optionally be included in the reaction sequence, or before or after the reaction sequence, or before or after the cyclic etch process as needed. For instance, in certain embodiments, a continuous etch step may be performed prior to the cyclic etch process. Exemplary embodiments as well as individual process steps and elements will be described in more detail below.

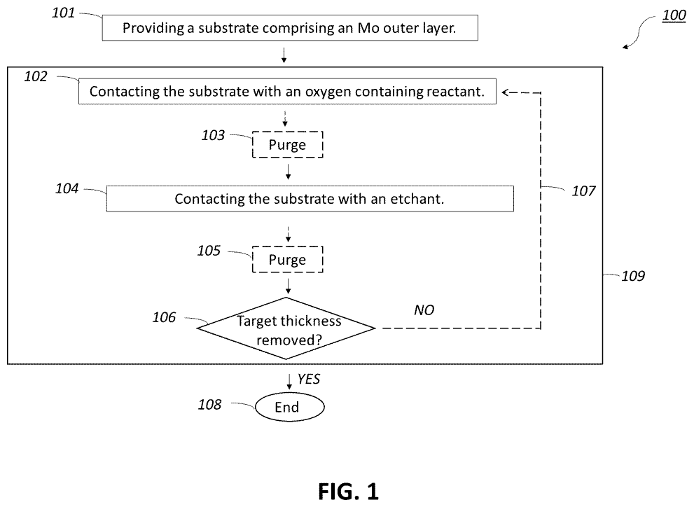

FIG. 1 is a process flow diagram 100 of an exemplary embodiment of a method for etching molybdenum disclosed herein. The method comprises providing a substrate comprising an Mo outer layer having an initial thickness in a reaction space 101, and performing a cyclic etch process 109. The cyclic etch process 109 comprises: exposing the substrate to an oxygen containing reactant 102, wherein the oxygen containing reactant oxidizes at least a portion of the Mo outer layer to molybdenum oxide; optionally purging the reaction space 103; exposing the substrate to an etchant (also referred to as a first etchant in certain places in the text below) 104 to convert the molybdenum oxide to a volatile Mo containing compound; and optionally purging the reaction space 105. Steps 102 and 104 may each be referred to as a sub-cycle and together, with the optional purging steps, 103 and 105, they define an etch cycle of the cyclic etch process 109. The etch cycle may be repeated 107 (n times) to reduce the thickness of the Mo outer layer. Other process steps may optionally be included in the etch cycle, or before or after an etch cycle, or before or after the cyclic etch process 109 as needed. For example, it will be understood that step 104 can be performed prior to step 102. Once a targeted thickness of molybdenum has been removed 106, the process is terminated 108. The targeted thickness of the removed molybdenum may be less than or equal to the initial thickness of the Mo outer layer.

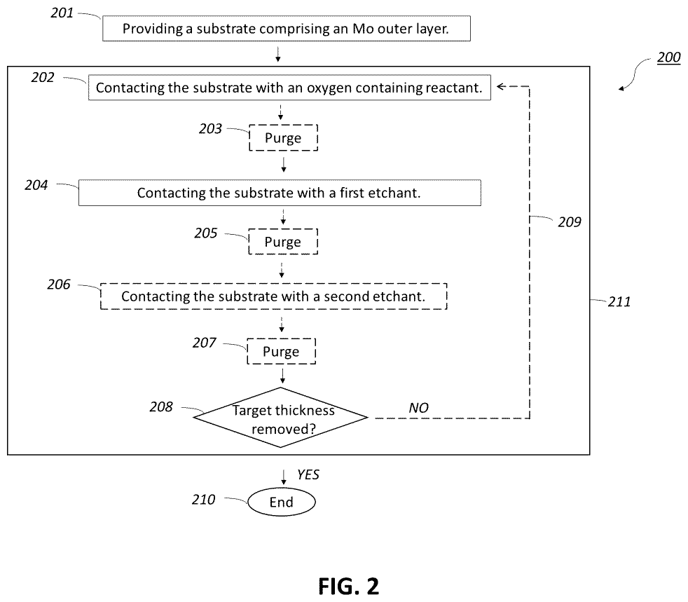

FIG. 2 is a process flow diagram 200 of another embodiment of a method for etching molybdenum disclosed herein. The method comprises providing a substrate comprising an Mo outer layer having an initial thickness in a reaction space 201, and performing a cyclic etch process 211. The cyclic etch process 211 comprises: exposing the substrate to an oxygen containing reactant 202, wherein the oxygen containing reactant oxidizes at least a portion of the Mo outer layer to molybdenum oxide; optionally purging the reaction space 203; exposing the substrate to a first etchant 204 to convert the molybdenum oxide to a volatile Mo containing compound; optionally purging the reaction space 205; exposing the substrate to a second etchant to remove a non-Mo containing oxide layer from the surface of the substrate 206; and optionally purging the reaction space 207. Steps 202, 204, and 206 may each be referred to as a sub-cycle and together, with the optional purging steps, 203, 205, and 207, they define an etch cycle of the cyclic etch process 211. The etch cycle may be repeated 209 (n times) to reduce the thickness of the Mo outer layer. Other process steps may optionally be included in the etch cycle, or before or after an etch cycle, or before or after the cyclic etch process 211 as needed. For example, it will be understood steps 204 and 206 may be performed prior to step 202. Once a targeted thickness of molybdenum has been removed, the process is terminated 210. The targeted thickness of the removed molybdenum is less than or equal to the initial thickness of the Mo outer layer.

In embodiments of the present disclosure, a substrate comprising an Mo outer layer is provided in a reaction space (e.g., one or more reaction chambers) (e.g., see 101 in FIG. 1 and 201 in FIG. 2). The reaction space is not particularly limited and may comprise one or more reaction chambers of a semiconductor processing apparatus. In some embodiments, a reaction chamber or reaction chambers in a flow-type reactor may be utilized. In some embodiments, a reaction chamber or reaction chambers in a showerhead-type reactor may be utilized. In some embodiments, a reaction chamber or reaction chambers in a space divided reactor may be utilized. In some embodiments, a reaction chamber or reaction chambers in a high-volume manufacturing-capable single wafer reactor may be utilized. In other embodiments, a reaction chamber or reaction chambers in a batch reactor may be utilized. For embodiments in which a batch reactor is used, the reaction chamber may house a number of wafers, for example, the number of wafers may be in the range of 10 to 200, or 50 to 150, or even 100 to 150. In any of these embodiments, the reactor may be configured as a thermal reactor and may lack a plasma generation unit or not use a plasma generation unit.

The substrate is also not particularly limited and may be a semiconductor wafer (or multiple semiconductor wafers). The substrate may comprise one or more material layers such as dielectric layers, insulating layers, conductive layers, sacrificial layers, and so forth, in addition to an Mo outer layer. The substrate may include various topological features, such as gaps, recesses, lines, trenches, vias, holes, or spaces between elevated portions formed within or on at least a portion of a layer of the substrate. The Mo outer layer may cover the entire surface of the substrate or only a portion of the substrate and may be present on the lateral surface(s) and/or the vertical surface(s) or sidewall(s) of the various topological features. Portions of the Mo outer layer may be covered with a masking layer, whereas the other portions are exposed.

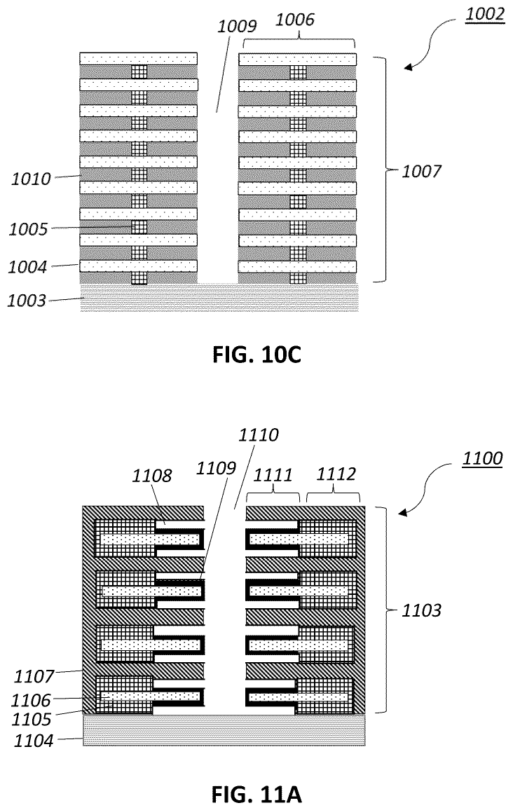

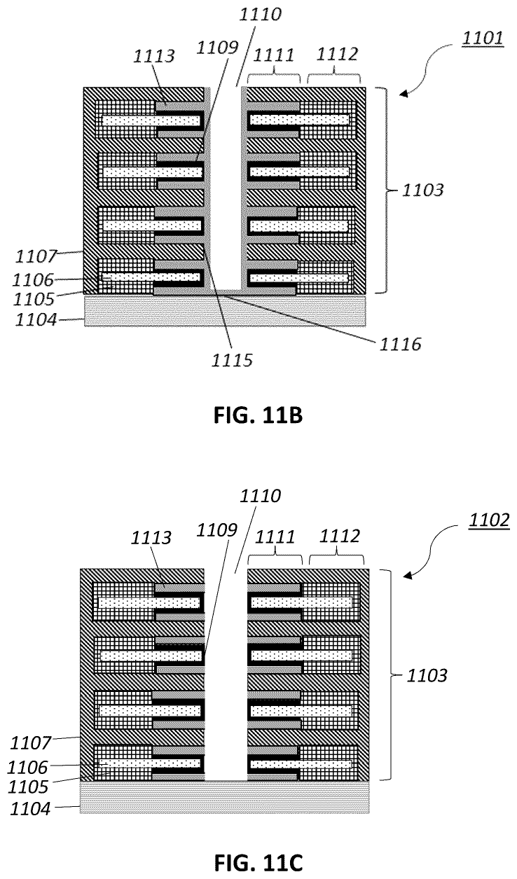

In some embodiments, the substrate comprises: at least one stacked structure formed from a plurality of stacked alternating materials layers, the at least one stacked structure comprising a top portion and sidewalls; and an Mo outer layer that is position on at least a portion of the side walls or on at least one of the sidewalls of the stacked structure(s) and optionally on at least a portion of the top portion of the stacked structure(s). The at least one stacked structure may comprise a plurality of stacked alternating insulating layers (e.g., silicon oxide) and conductive layers (e.g., molybdenum). (A pictorial representation of an exemplary embodiment of such a structure is shown in FIG. 10B, which is described below in more detail.) The at least one stacked structure may comprise a plurality of stacked alternating insulating layers (e.g., silicon oxide), channel layers, and conductive layers (e.g., molybdenum). (A pictorial representation of an exemplary embodiment of such a structure is shown in FIG. 11B, which is described below in more detail.) In some embodiments, the stacked structure may be an intermediate 3D NAND stack or an intermediate 3D DRAM stack. In this context, “intermediate” refers to a structure that is partially formed and further production steps are required to form the final structure.

The substrate comprising an Mo outer layer is exposed to an oxygen containing reactant to convert at least a portion of the Mo outer layer to molybdenum oxide (MoOₓ) (e.g., see 102 in FIG. 1 and 202 in FIG. 2). Oxidation of the Mo outer layer increases the reactivity of the outer layer enabling the subsequent etch step(s). Oxidation may be affected by thermal or plasma methods. In either case, the oxygen containing reactant is introduced into the reaction space and the Mo outer layer is contacted with the oxygen containing reactant. The degree of oxidation (i.e., the value of x in MoOₓ) as well as the thickness of the oxidized layer depends upon the nature of the oxygen containing reactant, the flux of the oxygen containing reactant on the substrate surface, and the exposure time of the substrate to the oxygen containing reactant, among other factors. For example, certain oxygen containing reactants can penetrate or diffuse into the substrate surface to various extents, thereby oxidizing more than just the outer most atomic or molecular layer. Higher fluxes and longer exposure times of the oxygen containing reactant may increase the thickness of the oxidized layer and the degree of oxidation, which may vary across the thickness of the oxidized layer. The thickness of the oxidized layer can impact the amount of material removed in the subsequent etch step(s); thus, these variables may be used to tune the etch rate of the process. The pulse time for introducing the oxygen containing reactant into the reaction space can be varied in different embodiments of the disclosure. Typical pulse times for introducing the oxygen containing reactant into the reaction space range from about 0.1 second up to about 10 minutes, typically from about 1 second to about 3 minute, or from about 1 second to about 1 minute, after which the reaction space may optionally be flushed or purged to remove unreacted oxygen containing reactant and other species, as applicable, from the reaction space (e.g., see 103 in FIG. 1 and 203 in FIG. 2).

In some embodiments, the Mo outer layer is oxidized under thermal conditions. Under thermal conditions, the reaction(s) may be promoted by increasing the temperature relevant to ambient temperature. Generally, the temperature increase provides the energy needed for the reaction(s) to proceed in the absence of other external energy sources, such as plasma, radicals, or other forms of radiation. In other words, the reaction does not employ reactive species generated by a plasma and may therefore be referred to as “plasma-free”. Thermal methods may be preferred where isotropic etching is desired and/or for the formation of high aspect ratio structures. Suitable oxygen containing reactants include, but are not limited to, oxygen (O₂), ozone (O₃), water (H₂O), hydrogen peroxide (H₂O₂), an organic peroxide (ROOH, where R is an alkyl or an aryl group), an alcohol (ROH, where R is an alkyl or an aryl group), nitrogen dioxide (NO₂), nitrous oxide (N₂O), nitric oxide (NO), dinitrogen pentoxide (N₂O₅), pyridine oxide (C₅H₅NO), an amine oxide (R₃NO, where each R is independently an alkyl group or an aryl group, and/or two or more R groups may be bonded to one another to form a ring structure), and combinations thereof. In some embodiments, the oxygen containing reactant is oxygen, ozone, nitrous oxide, or a combination thereof. In some embodiments, the oxygen containing reactant is free of plasma species and the substrate is not exposed to plasma species. For example, the oxygen containing reactant may be free of one or more of ionic species, radical species, atoms, metastable species, and excited species.

In other embodiments, the Mo outer layer is oxidized under non-thermal conditions using a plasma. Plasma based methods may be preferred for applications requiring lower temperatures and/or where anisotropic etching is desired. In these embodiments, the oxygen containing reactant is formed by providing an oxygen containing feed gas into a plasma source. The plasma source may be a direct plasma source or a remote plasma source. The power for generating the plasma can be varied in different embodiments of the disclosure. In some embodiments, the power for generating the plasma is from about 10 W to about 2,000 W, typically from about 20 W to about 1,000 W, or more typically from about 20 W to about 500 W. Suitable oxygen containing feed gasses include, but are not limited to, oxygen (O₂), ozone (O₃), water (H₂O), hydrogen peroxide (H₂O₂), an organic peroxide (ROOH, where R is an alkyl or an aryl group), an alcohol (ROH, where R is an alkyl or an aryl group), nitrogen dioxide (NO₂), nitrous oxide (N₂O), nitric oxide (NO), dinitrogen pentoxide (N₂O₅), pyridine oxide (C₅H₅NO), an amine oxide (R₃NO, where each R is independently an alkyl group or an aryl group, and two or more R groups may be bonded to one another to form a ring structure), and combinations thereof. As such, the oxygen containing reactant may comprise O₂, O₃, H₂O, H₂O₂, ROOH, ROH, NO₂, N₂O, NO, N₂O₅, C₅H₅NO, R₃NO, combinations thereof, and oxygen plasma species formed therefrom. In some embodiments, the oxygen containing reactant comprises an oxygen plasma species. In some embodiments, the oxygen containing reactant is an oxygen plasma species. Examples of oxygen plasma species include, but are not limited to, atomic oxygen (O), excited diatomic oxygen (e.g., singlet oxygen (¹O₂)), ozone (O₃), hydroxyl radical (OH), peroxyl radical (e.g., HO₂), nitric oxide (NO), and combinations thereof. The oxygen containing feed gas may optionally be mixed or co-fed with a carrier gas, such as a noble gas selected from the group consisting of helium (He), neon (Ne), argon (Ar), krypton (Kr), xenon (Xe), and mixtures thereof. The excited species from noble gases in the plasma may, in some circumstances, help facilitated the reaction, as well as help in the formation and ignition of the plasma.

The substrate is exposed to an etchant (also referred to as a first etchant in some places herein) (e.g., sec 104 in FIG. 1 and 204 in FIG. 2). Exposure of the substrate to the etchant occurs under thermal conditions; thus, the etchant is free of plasma species and the substrate is not exposed to plasma species. The etchant converts the MoOₓ outer layer to a volatile Mo containing compound, which is removed from the surface of the substrate. In some embodiments, the volatile Mo containing compound is a molybdenum oxyhalide (MoOₓX_{y}). For example, in some embodiments, the volatile Mo containing compound may be a molybdenum oxychloride (MoOₓCl_{y}), such as molybdenum tetrachloride oxide (MoOCl₄) (melting point=101° C.) and/or molybdenum dichloride dioxide (MoO₂Cl₂) (melting point=175° C.), both of which may readily be removed from the substrate surface. Other oxychlorides may be formed in addition to or alternatively to MoOCl₄ and MoO₂Cl₂. In other embodiments, the volatile Mo containing compound may be a molybdenum oxybromide (MoOₓBr_{y}).

A number of suitable etchants may be utilized as long as the reaction of the etchant with MoOₓ is favorable and leads to the formation of a volatile Mo containing compound. Generally, a reaction may be considered favorable if the Gibbs free energy change for the reaction is negative (i.e., ΔₘₓG(T)<0). The free energy change for a given reaction is a function of temperature (T). The temperature of the substrate is typically maintained such that reaction of the etchant with MoOₓ is spontaneous, whereas the reaction of the etchant with Mo is not spontaneous. In some embodiments, the etchant comprises one or more sulfur-chlorine bond(s) (i.e., S—Cl bond(s)) and/or one or more sulfur-bromine bond(s) (i.e., S—Br bond(s)). Suitable etchants comprising S—Cl bond(s) may include, but not be limited to, thionyl chloride (SOCl₂), sulfuryl chloride (SO₂Cl₂), and disulfur dichloride (S₂Cl₂). Suitable etchants comprising S—Br bond(s) may include, but not be limited to, thionyl bromide (SOBr₂), sulfuryl bromide (SO₂Br₂), and disulfur dibromide (S₂Br₂). In some embodiments, the etchant comprises one or more phosphorous-chlorine bond(s) (i.e., P—Cl bond(s)) and/or one or more phosphorous-bromine bond(s) (i.e., P—Br bond(s)). Suitable etchants comprising P—Cl bond(s) may include, but not be limited to, phosphorus pentachloride (PCl₅), phosphorus trichloride (PCl₃), and phosphoryl chloride (POCl₃). Suitable etchants comprising P—Br bond(s) may include, but not be limited to, phosphorus pentabromide (PBr₅), phosphorus tribromide (PBr₃), and phosphoryl bromide (POBr₃). In some embodiments, the etchant comprises one or more silicon-chlorine bond(s) (i.e., Si—Cl bond(s)) and/or one or more silicon-bromine bond(s) (i.e., Si—Br bond(s)). Suitable etchants comprising Si—Cl bond(s) may include, but not be limited to, silicon tetrachloride (SiCl₄), trichlorosilane (SiHCl₃), dichlorosilane (SiH₂Cl₂), chlorosilane (SiH₃Cl), and hexachlorodisilane (Si₂Cl₆). Suitable etchants comprising Si—Br bond(s) may include, but not be limited to, silicon tetrabromide (SiBr₄), tribromosilane (SiHBr₃), dibromosilane (SiH₂Br₂), bromosilane (SiH₃Br), and hexabromodisilane (Si₂Br₆). The etchant may be in gaseous form, or it may have sufficient vapor pressure at or near room temperature, or above room temperature, so that it is transported into the reaction space and to the substrate surface. The etchant may be heated to provide sufficient vapor pressure and/or entrained in a flow of an inert carrier gas (e.g., nitrogen and/or a noble gas such as helium (He) and argon (Ar)) and introduced into the reaction space. The flow rate and/or the pulse time for the etchant into the reaction space may optimized so that the MoOₓ outer layer is fully removed from the substrate surface. Typical pulse times for introducing the etchant into the reaction space range from about 0.1 second up to about 10 minutes, typically from about 1 second to about 3 minute, or from about 1 second to about 1 minute, after which the reaction space may optionally be flushed or purged to remove unreacted etchant and reaction by-products, such as, for example, the volatile Mo containing species, from the reaction space (e.g., see 105 in FIG. 1 and 205 in FIG. 2).

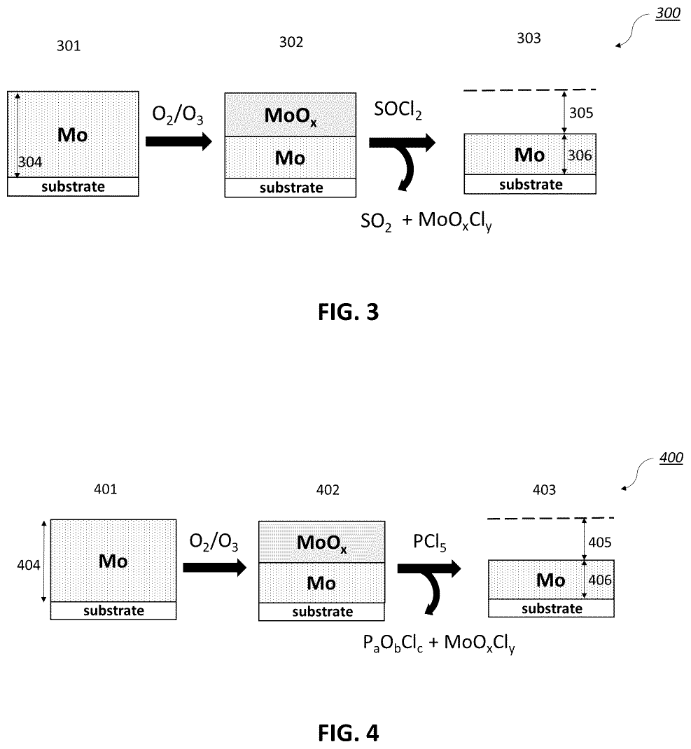

In an exemplary embodiment of the disclosure, the etchant comprises thionyl chloride (SOCl₂). In some embodiments, the etchant is SOCl₂. Thionyl chloride has a boiling point of 74.6° C. and a vapor pressure of 15.7 kPa at 25° C. Without wishing to be bound by a particular mechanism, it is hypothesized that, when the etchant is SOCl₂, the etch cycle proceeds as shown pictorially 300 in FIG. 3. In the first step, structure 301 comprising a substrate comprising an Mo outer layer having a first thickness 304 is exposed to an oxygen containing reactant (e.g., O₂ and/or O₃, although other oxygen containing reactants may be used) to convert at least a portion of the Mo outer layer to MoOₓ. The resulting structure 302 comprises a molybdenum containing film comprising an outer layer comprising MoOₓ that is positioned over a bulk region comprising metallic molybdenum (Mo). Next, the structure 302 is exposed to SOCl₂. The reaction products, MoOₓCl_{y} and SO₂, are removed from the surface of the substrate by diffusion and/or by purging to reveal structure 303 comprising an Mo outer layer having a second thickness that is less than the first thickness 306. The process may be repeated (for example, as shown in 109 in FIG. 1) to remove a targeted thickness of molybdenum 305 from the surface of the substrate.

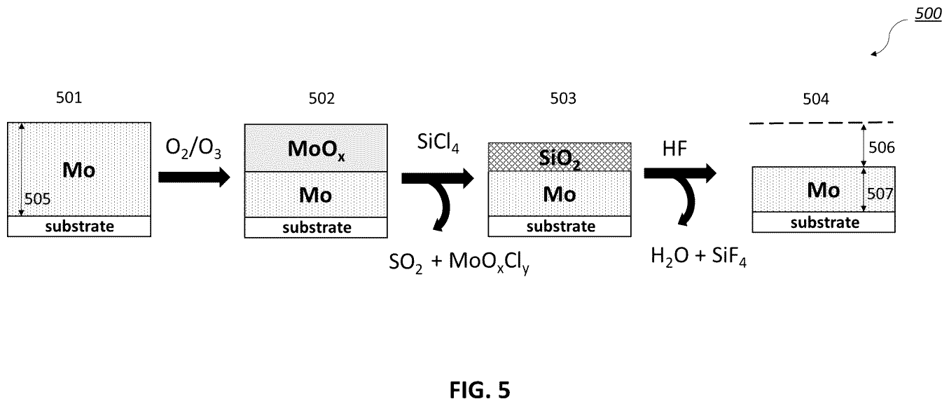

In another exemplary embodiment of the disclosure, the etchant comprises phosphorus pentachloride (PCl₅). In some embodiments, the etchant is PCl₅. Phosphorous pentachloride is a yellowish-white solid that sublimes at 166.8° C. and has a vapor pressure of 4.58 kPa at 100° C. Without wishing to be bound by a particular mechanism, it is hypothesized that, when the etchant is PCl₅, the etch cycle proceeds as shown pictorially 400 in FIG. 4. In the first step, structure 401 comprising a substrate comprising an Mo outer layer having a first thickness 404 is exposed to an oxygen containing reactant (e.g., O₂ and/or O₃, although other oxygen containing reactants may be used) to convert at least a portion of the Mo outer layer to MoOₓ. The resulting structure 402 comprises a molybdenum containing film comprising an outer layer comprising MoOₓ that is positioned over a bulk region comprising metallic molybdenum (Mo). Next, structure 402 is exposed to PCl₅ to convert the MoOₓ layer to a volatile MoOₓCl_{y} compound. The reaction also produces a volatile phosphorus containing compound, which may generally be expressed as PₐO_{b}Cl_{c}, where the subscripts “a”, “b”, and “c” are integers and indicate that the stoichiometry may vary. PₐO_{b}Cl_{c} may be any one of POCl₃, P₂O₅, and/or P₄O₆. The reaction products, MoOₓCl_{y} and PₐO_{b}Cl_{c}, are removed from the surface of the substrate by diffusion and/or by purging to reveal structure 403 comprising an Mo outer layer having a second thickness 406 that is less than the initial thickness 404. The process may be repeated (for example, as shown in 109 in FIG. 1) to remove a targeted thickness of molybdenum from the surface of the substrate 405.

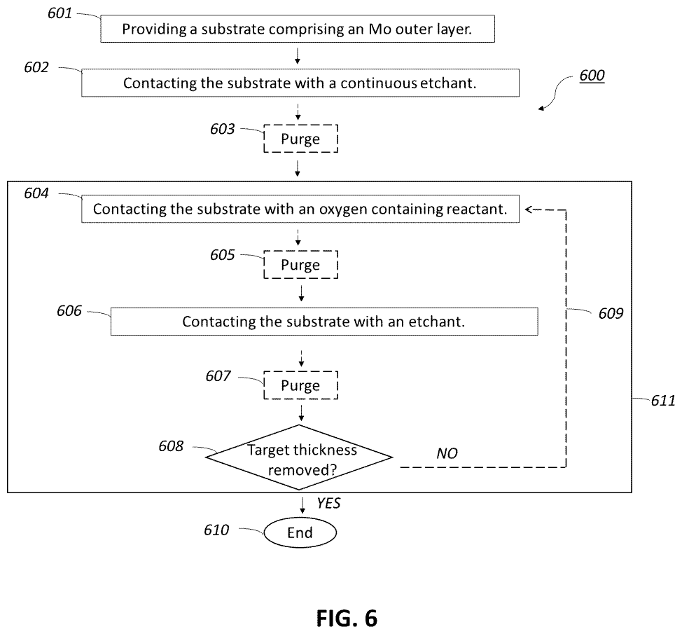

In yet another exemplary embodiment of the disclosure, the etchant is silicon tetrachloride (SiCl₄). In some embodiments, the etchant is SiCl₄. Silicon tetrachloride has a boiling point of 57.65° C. and a vapor pressure of 25.9 kPa at 20° C. Without wishing to be bound by a particular mechanism, it is hypothesized that, when the etchant is SiCl₄, the etch cycle proceeds as shown pictorially 500 in FIG. 5. In the first step, structure 501 comprising a substrate comprising an Mo outer layer having a first thickness 505 is exposed to an oxygen containing reactant (e.g., O₂ and/or O₃, although other oxygen containing reactants may be used) to convert at least a portion of the Mo outer layer to MoOₓ. The resulting structure 502 comprises a molybdenum containing film comprising an outer layer comprising MoOₓ that is positioned over a bulk region comprising metallic molybdenum (Mo). Next, structure 502 is exposed to SiCl₄ to convert the MoOₓ layer to a volatile MoOₓCl_{y} compound which is removed from the surface of the substrate by diffusion and/or by purging. The reaction also produces SiO₂ as a solid layer on the substrate surface 503 (shown in structure 503) and a second etch step is required to reveal structure 504 comprising an Mo outer layer having a second thickness that is less than the initial thickness 507. For example, SiO₂ may readily be removed by exposing the substrate to HF. The process may be repeated (for example, as shown in 211 in FIG. 2) to remove a targeted thickness of molybdenum from the surface of the substrate 506.

The various process steps of the etch cycle discussed above may be sequentially repeated to remove a targeted thickness of molybdenum from the surface of the substrate. As an example, referring to the embodiment shown in FIG. 1, the method may comprise repeating 107 steps 102 and 104 one or more (n) times to remove a targeted thickness of molybdenum from the surface of the substrate; or repeating 107 steps 102, 103, 104, and 105 one or more (n) time to remove a targeted thickness of molybdenum from the surface of the substrate; or repeating 107 steps 102, 103, and 104 or steps 102, 104, and 105 one or more (n) time to remove a targeted thickness of molybdenum from the surface of the substrate; or any combinations thereof. In another example, referring to the embodiment shown in FIG. 2, the method may comprise repeating 209 steps 202, 204, and 206 one or more (n) times to remove a targeted thickness of molybdenum from the surface of the substrate; or repeating 209 steps 202, 203, 204, 205, 206, and 207 one or more (n) time to remove a targeted thickness of molybdenum from the surface of the substrate; or repeating 209 steps 202, 204, and 206, with any of steps 203, 205, and 207 one or more (n) time to remove a targeted thickness of molybdenum from the surface of the substrate; or any combinations thereof. Other steps may be inserted in the process as needed. For example, other reaction steps and/or etching steps may be performed before or after or between the n repeating cycles. The number of repeated cycles (n) is not particularly limited and depends upon the targeted Mo thickness that is to be removed and the etch rate of molybdenum. In some embodiments, the Mo outer layer is etched at a rate from about 0.1 Å to about 5 Å per etch cycle, such as at a rate from about 0.1 Å to about 1.0 Å per etch cycle, or even at a rate from about 0.3 Å to about 0.5 Å per etch cycle. In some embodiments, the Mo outer layer is etched at a rate from about 0.1 Å to about 0.5 Å per etch cycle, or at a rate from about 0.2 Å to about 0.5 Å per etch cycle, or at a rate from about 0.3 Å to about 0.5 Å per etch cycle. In some embodiments, the process is repeated until a targeted thickness of the Mo outer layer has been removed. In some embodiments, the process is repeated until the entire Mo outer layer has been removed. In some embodiments, the Mo outer layer may have an initial thickness (pre-etch) of between about 0.5 nm and about 20 nm, or between about 2 nm and about 15 nm, or between about 4 nm and about 15 nm. In some embodiments, the Mo outer layer may have an initial thickness (pre-etch) of less than about 20 nm, or less than about 15 nm, or less than about 12 nm, or less than about 10 nm, or less than about 8 nm, or less than about 4 nm, or less than about 2 nm. In some embodiments, the number of repeated cycles (n) is between about 1 and about 5,000, between about 1 and about 2,000, between about 1 and about 1,000, between about 1 and about 500, between 1 and about 200, between about 1 and about 100, or typically between about 10 and about 1,000, typically between about 10 and about 500, typically between about 10 and about 200, typically between about 10 and about 100, or more typically between about 50 and about 1,000, or more typically between about 50 and about 500, or more typically between about 50 and about 200.

In certain embodiments, a continuous etch step is performed prior to the cyclic etch process described above. In these embodiments, the continuous etch step is used to reduce the thickness of the Mo outer layer to an intermediate thickness, and then the cyclic etch process is used to further reduce the thickness of the Mo outer layer to a final thickness or to remove the Mo outer layer entirely. Use of the continuous etch step allows for molybdenum to be removed rapidly, without the need to sequentially introduce multiple reactants into the reaction space; whereas the cyclic etch process allows for molybdenum to be removed in a well-defined, controlled manner. The continuous etch step may be performed by exposing the substrate comprising an Mo outer layer having an initial thickness to a continuous etchant, thereby reducing the thickness of the Mo outer layer to an intermediate thickness. The amount of molybdenum removed (i.e., the difference between the initial thickness and intermediate thickness) depends upon the nature of the continuous etchant, the flux of the continuous etchant to the substrate surface, and the exposure time of the substrate surface to the continuous etchant, among other factors. In some embodiments, the Mo outer layer may have an initial thickness (pre-etch) of between about 5 nm and about 20 nm, and a continuous etch step is used to reduce the thickness of the Mo outer layer to an intermediate thickness of less than about 10 nm, or less than about 5 nm, or less than about 3 nm. In some embodiments, the Mo outer layer may have an initial thickness (pre-etch) of between about 5 nm and about 15 nm, and a continuous etch step is used to reduce the thickness of the Mo outer layer to an intermediate thickness of less than about 10 nm, or less than about 5 nm, or less than about 3 nm.

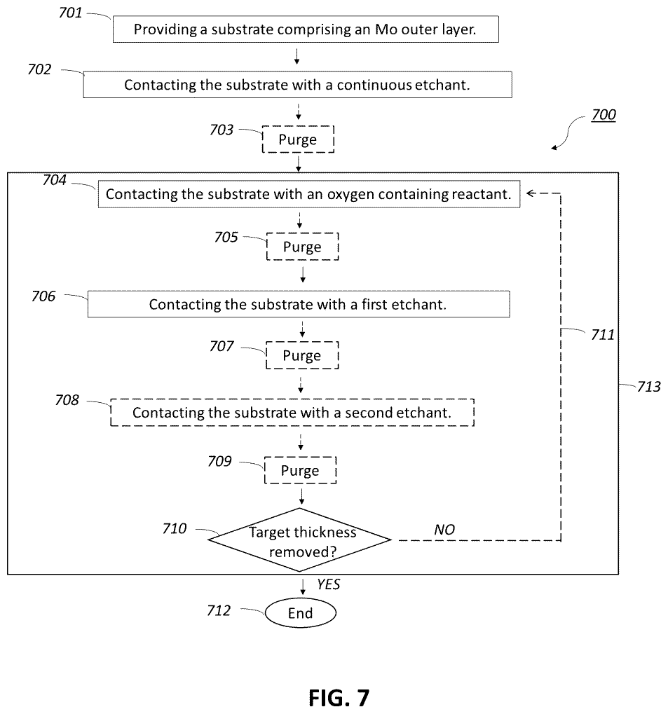

FIG. 6 a shows process diagram 600 for an exemplary embodiment of the disclosure, wherein a continuous etch step 602 is performed prior to a cyclic etch process 611. (Note that steps 604 to 611 in FIG. 6 mirror steps 102 to 109 in FIG. 1.) The method comprises: providing a substrate comprising an Mo outer layer having an initial thickness in a reaction space 601; exposing the substrate to a continuous etchant 602, to reduce the thickness of the Mo outer layer to an intermediate thickness; optionally purging the reaction space 603; and performing a cyclic etch process 611. The cyclic etch process 611 comprises: exposing the substrate to an oxygen containing reactant 604, wherein the oxygen containing reactant oxidizes at least a portion of the Mo outer layer having an intermediate thickness to molybdenum oxide; optionally purging the reaction space 605; exposing the substrate to an etchant (also referred to as a first etchant in places throughout the disclosure) 606 to convert the molybdenum oxide to a volatile Mo containing compound; and optionally purging the reaction space 607. Step 602 is a continuous etch process. Steps 604 to 607 define one etch cycle of the cyclic etch process 611. The etch cycle, 604 to 606, together with the optional purge steps, 605 and 607, may be repeated 609 (n times) to reduce the thickness of the Mo outer layer. Once a targeted thickness of molybdenum has been removed 608, the process is terminated 610. The targeted thickness of removed molybdenum may be less than or equal to the initial thickness of the Mo outer layer.

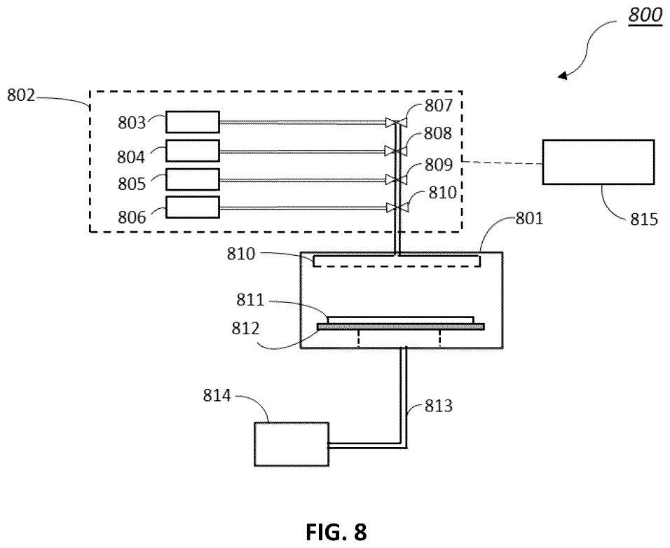

FIG. 7 a shows process diagram 700 for another exemplary embodiment of the disclosure, wherein a continuous etch step 702 is performed prior to a cyclic etch process 713. (Note that steps 704 to 713 in FIG. 7 mirror steps 202 to 211 in FIG. 2.) The method comprises: providing a substrate comprising an Mo outer layer having an initial thickness in a reaction space 701; exposing the substrate to a continuous etchant 702, to reduce the thickness of the Mo outer layer to an intermediate thickness; optionally purging the reaction space 703; and performing a cyclic etch process 713. The cyclic etch process 713 comprises: exposing the substrate to an oxygen containing reactant 704, wherein the oxygen containing reactant oxidizes at least a portion of the Mo outer layer having an intermediate thickness to molybdenum oxide; optionally purging the reaction space 705; exposing the substrate to a first etchant 706 to convert the molybdenum oxide to a volatile Mo containing compound; optionally purging the reaction space 707; exposing the substrate to a second etchant to remove a non-Mo containing oxide layer from the surface of the substrate 708; and optionally purging the reaction space 709. Step 702 is a continuous etch process. Steps 704, 706, and 708, together with the optional purge steps, 705, 707, and 709, define one etch cycle of the cyclic etch process 713. The etch cycle, 704 to 709, may be repeated 711 (n times) to reduce the thickness of the Mo outer layer. Once a targeted thickness of molybdenum has been removed 710, the process is terminated 712. The targeted thickness of removed molybdenum may be less than or equal to the initial thickness of the Mo outer layer.

Suitable continuous etchants include, but are not limited to, molybdenum pentachloride (MoCl₅), thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof. In some embodiments, the continuous etchant comprises molybdenum pentachloride (MoCl₅), which spontaneously etches molybdenum at room temperature and above. In some embodiments, the continuous etchant is MoCl₅. In other embodiments, the continuous etchant and the first etchant are the same chemical compound, and the continuous etch step and the cyclic etch process are performed under different reaction conditions such that the Mo outer layer is etched in the continuous etch step but not, or not substantially, etched in the cyclic etch process. For example, during the continuous etch process, the substrate may be maintained at a first temperature such that the reaction of the etchant with Mo is spontaneous and, during the cyclic etch process, the substrate may be maintained at a second temperature such that the reaction of the etchant with MOₓ is spontaneous but the reaction of the etchant with Mo is not spontaneous. Generally, in these embodiments, the first temperature is greater than the second temperature. In some of these embodiments, the continuous etchant comprises SOCl₂. In some of these embodiments, the continuous etchant is SOCl₂. In some of these embodiments, the continuous etchant and the first etchant are SOCl₂. In some of these embodiments, the continuous etchant comprises one or both of PCl₅ and PCl₃. In some of these embodiments, the continuous etchant is one or both of PCl₅ and PCl₃. In some of these embodiments, the continuous etchant and the first etchant are one or both of PCl₅ and PCl₃. In some of these embodiments, the continuous etchant comprises SiCl₄. In some of these embodiments, the continuous etchant is SiCl₄. In some of these embodiments, the continuous etchant and the first etchant are SiCl₄.

As will be appreciated by one of skill in the art, a number of process parameters may impact the etching rate of the Mo outer layer. These process parameters include, but are not limited to, the temperature of the substrate, the pressure inside of the reaction space, and the exposure time of the substrate surface to the oxygen containing reactant and the etchant(s), the flux of the oxygen containing reactant and the etchant to the substrate surface, among other things. Optimization of these parameters to obtained suitable etch rates can be achieved based on routine work and such optimization is within the capabilities of one of skill in the art.

The methods according to the current disclosure may be performed at an elevated temperature. For instance, the substrate may be maintained at an elevated temperature. In some embodiments, the method is performed by maintaining the substrate temperature from about 40° C. to about 600° C., typically from about 100° C. to about 500° C., or from about 100° C. to about 475° C., or from about 100° C. to about 450° C., or from about 100° C. to about 425° C., or from about 100° C. to about 400° C., or from about 100° C. to about 375° C., or from about 100° C. to about 350° C., or from about 100° C. to about 325° C., or from about 100° C. to about 300° C., or from about 100° C. to about 275° C., or from about 100° C. to about 250° C. In some embodiments, the method is performed by maintaining the substrate temperature at less than about 450° C., or less than about 425° C., or less than about 400° C. In some embodiments, the method is performed by maintaining the substrate temperature at about 50° C., or at about 75° C., or at about 100° C., or at about 125° C., or at about 150° C., or at about 175° C., a or t about 200° C., or at about 225° C., or at about 250° C., or at about 275° C., or at about 300° C., or at about 325° C., or at about 350° C., or at about 375° C., or at about 400° C., or at about 425° C., or at about 450° C., or at about 475° C., or at about 500° C., or at about 525° C., or at about 550° C., or at about 575° C., or at about 600° C. In some embodiments, the method is performed under thermal conditions (i.e., the substrate is not exposed to a plasma species) and the substrate temperature may be maintained at a temperature from about 300° C. to about 600° C., typically from about 300° C. to about 450° C., or from about 300° C. to about 425° C., or from about 300° C. to about 400° C. In other embodiments, the substrate is exposed to an oxygen plasma species and the substrate temperature may be maintained at a temperature from about 100° C. to about 400° C., typically from about 100° C. to about 300° C., or more typically from about 100° C. to about 250° C. In certain embodiments, where a continuous etch step is performed prior to the cyclic etch process, the substrate may be maintained at a first temperature during the continuous etch step and a second temperature during the cyclic etch process. In some of these embodiments, the first temperature may be higher than the second temperature. In some other of these embodiments, the first temperature may be lower than the second temperature.

The methods according to the current disclosure may be performed at reduced pressure. In some embodiments, the pressure within the reaction space during the etch process is less than about 500 Torr, typically from about 0.1 Torr to about 500 Torr, or from about 0.5 Torr to about 100 Torr, or from about 1 Torr to about 20 Torr. In some embodiments, the pressure within the reaction space during the etch process is less than about 100 Torr, less than about 50 Torr, less than about 20 Torr, or less than about 10 Torr. In some embodiments, the pressure within the reaction space during an etch cycle is lower than about 20 Torr. In some embodiments, the pressure within the reaction space during an etch cycle is lower than about 10 Torr. In some embodiments, the pressure within the reaction space during an etch cycle is higher than about 1 Torr. In some embodiments, the pressure within the reaction space during an etch cycle is higher than about 5 Torr. In some embodiments, the pressure within the reaction space during a etch process is between about 1 Torr and about 25 Torr. In some embodiments, the process may be performed in constant pressure. In some embodiments, the pressure in the reaction space during a first sub cycle is different than the pressure inside the reaction chamber during a second sub cycle or a third sub cycle. For example, a first pressure in the reaction space during the oxidation reaction may be higher than a second pressure in the reaction space during the etch reaction step(s). Alternatively, a first pressure in the reaction space during the oxidation reaction may be lower than a second pressure in the reaction space during the etch reaction step(s). In other instances, a first pressure within the reaction space during the oxidation reaction may be the same or substantially the same as second pressure in the reaction space during the etch reaction step(s). In certain embodiments, where a continuous etch step is performed, the pressure in the reaction space during the continuous etch step may be different than the pressure inside the reaction chamber during the cycle etch process. For example, a first pressure in the reaction space during the continuous etch step may be higher than a second pressure in the reaction space during the cycle etch process. Alternatively, a first pressure in the reaction space during the continuous etch step may be lower than a second pressure in the reaction space during the cycle etch process. In other instances, a first pressure within the reaction space during the continuous etch step may be the same or substantially the same as a second pressure in the reaction space during the cycle etch process.

Another aspect of the disclosure relates to systems for etching a molybdenum containing film using the methods disclosed herein. In some embodiments, the system is a semiconductor processing apparatus that comprises a reaction space (i.e., at least one reaction chamber) for accommodating a substrate comprising an Mo outer layer. The semiconductor processing apparatus may comprise one reaction chamber, two reaction chambers, three reaction chambers, four reaction chambers, or more. In some embodiments, a reaction chamber or reaction chambers in a flow-type reactor may be utilized. In some embodiments, a reaction chamber or reaction chambers in a showerhead-type reactor may be utilized. In some embodiments, a reaction chamber or reaction chambers in a space divided reactor may be utilized. In some embodiments, a reaction chamber or reaction chambers in a high-volume manufacturing-capable single wafer reactor may be utilized. In other embodiments, a reaction chamber or reaction chambers in a batch reactor may be utilized. The semiconductor processing apparatus further comprises a means for exposing the substrate to an oxygen containing reactant to convert at least a portion of the Mo outer layer to molybdenum oxide (MoOₓ) and a means for exposing the substrate to an etchant to convert the MoOₓ to a volatile Mo containing compound, and optionally a means for purging the reaction space between the exposing steps. The semiconductor processing apparatus may further comprise one or more of a means for exposing the substrate to additional reactants and a means for heating the substrate. In some embodiments, semiconductor processing apparatus further comprises a means for generating a plasma. In other embodiments, semiconductor processing apparatus does not comprise a means for generating a plasma. These various elements and how they pertain to the disclosed methods are described in detail in the above text.

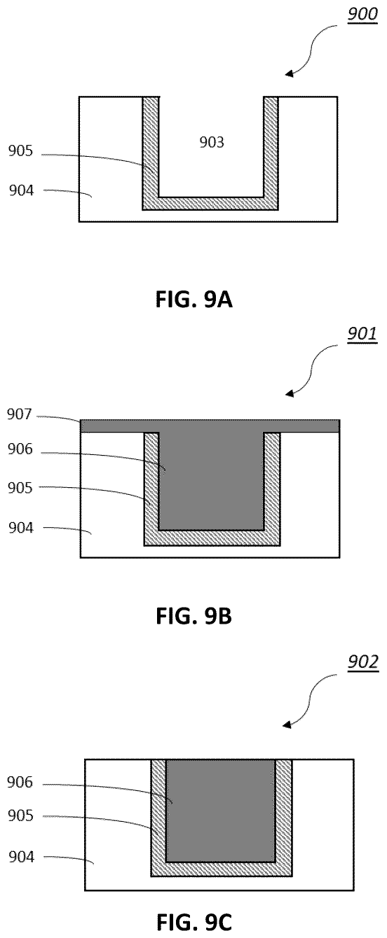

FIG. 8 shows a schematic diagram of an exemplary embodiment of a semiconductor processing apparatus 800 according to the present disclosure. Gaseous reactants are provided into the reaction chamber 801 through an injector system 802. The injector system 802 is configured to provide an oxygen containing reactant from a first source 803, a first etchant from second source 804, optionally a second etchant from a third source 805, and optionally a continuous etchant from a fourth source 806. The injector system may further comprise one or more other gases sources (not shown), for example, for providing purge gases and carrier gases (e.g., nitrogen and/or a noble gas, such as He, Ne, Ar, Kr, Xe, and combinations thereof) to the reaction chamber, and a means for heating the various reactant sources and corresponding gas lines, if required, to facilitate their introduction into the reaction chamber 807. The various gasses flow into the reaction chamber 801 through a shower head 810 that is positioned directly above a susceptor 812 on which the substrate 811 is placed. In some embodiments, the reaction chamber 801 may further comprise one or more heating elements (not shown) that are in thermal communication with the substrate 811 and one or more thermocouples (not shown), to maintain a temperature of the substrate 811 at a set temperature. Unreacted gasses and gaseous reaction by-products exit the reaction chamber 801 through an exhaust line 813 that is coupled to a vacuum pump 814. Optionally, in certain embodiments, the semiconductor processing apparatus 800 further comprises a plasma unit comprising a plasma generator (e.g., a RF power generator or microwave power generator) (not shown), which may be configured to form a plasma between the shower head 810 and the susceptor 812 or, alternatively, to form a plasma remotely upstream of the reaction chamber 801. The semiconductor processing apparatus also comprises a controller 815 operably connected to the first, second, third, and fourth valves, 807-810, and other components (not shown). The controller 815 is configured and programmed to independently control (e.g., turn on and off, etc.) the supply of the various gasses (e.g., the oxygen containing reactant, the first etchant, and optionally the second etchant, the continuous etchant, carrier gasses and purging gasses, etc.), the plasma generator (if present), and other components, as required, to etch the Mo outer layer.

In some embodiments, the controller 815 is configured and programed to perform a cyclic etch process comprising a first operation and a second operation, among other things. In the first operation, the controller 815 opens valve 807 to flow the oxygen containing reactant from the first source 803 into the reaction chamber 801 and, after a set period of time, the controller 815 closes the valve 807 to the first source 803 (e.g., 102 in FIG. 1 and 604 in FIG. 6). In certain embodiments, where the semiconductor processing apparatus 800 comprises a plasma unit (not shown), the controller 815 may be configured and programed to pulses (turn on, then off) the plasma generator while flowing the oxygen containing reactant from the first source 803 into the reaction chamber 801. Next, in the second operation, the controller 815 opens valve 808 to flow the first etchant from the second source 804 into the reaction chamber 801 and, after a set period of time, the controller 815 closes the valve 808 to the second source 804 (e.g., 104 in FIG. 1 and 606 in FIG. 6). The controller 815 may be programed to repeat the first operation and the second operation (n times) to remove a targeted thickness of the Mo outer layer from the substrate 811. The controller 815 may optionally be configured and programed to perform other additional operations before, after and/or during the cyclic etch process.

In other embodiments, the controller 815 is configured and programed to perform a cyclic etch process comprising a first operation, a second operation, and a third operation, among other things. In the first operation, the controller 815 opens valve 807 to flow the oxygen containing reactant from the first source 803 into the reaction chamber 801 and, after a set period of time, the controller 815 closes the valve 807 to the first source 803 (e.g., 202 in FIG. 2 and 704 in FIG. 7). In certain embodiments, where the semiconductor processing apparatus 800 comprises a plasma unit (not shown), the controller 815 may be configured and programed to pulses (turn on, then off) the plasma generator while flowing the oxygen containing reactant from the first source 803 into the reaction chamber 801. Next, in the second operation, the controller 815 opens valve 808 to flow the first etchant from the second source 804 into the reaction chamber 801 and, after a set period of time, the controller 815 closes the valve 808 to the second source 804 (e.g., 204 in FIG. 2 and 706 in FIG. 7). Then, in the third operation, the controller 815 opens valve 809 to flow the second etchant from the third source 805 into the reaction chamber 801 and, after a set period of time, the controller 815 closes the valve 809 to the third source 805 (e.g., 206 in FIG. 2 and 708 in FIG. 7). The controller 815 may be programed to repeat the first operation, the second operation, and the third operation (n times) to remove a targeted thickness of the Mo outer layer from the substrate 811. The controller 815 may optionally be configured and programed to perform other additional operations before, after and/or during the cyclic etch process.

The controller 815 may be further configured and programed to perform other operations. For example, the controller 815 may be operably connected to a purge gas source (not shown) and configured and programed to open a valve to the purge gas source to flow a purge gas into the reaction chamber 801 and, after a set period of time, close the valve to the purge gas. In another example, the controller 815 may be operably connected to one or more heaters (not shown) and one or more thermocouples (not shown) and configured and programed to control a temperature of the at least one heating element to maintain a temperature of the substrate 811 at a set temperature. In yet another example, in certain embodiments, the controller 815 may be further configured and programed to perform a continuous etch operation, prior to commencing the first operation. In some embodiments, the controller 815 may be programed to, prior to the first operation, open valve 810 to the fourth source 806 to flow a continuous etchant into the reaction chamber 801 and, after a set period of time, the controller 815 closes the valve 810 to the fourth source 806 (e.g., 602 in FIG. 6 and 702 in FIG. 7). Alternatively, in other embodiments, the first etchant and the continuous etchant are the same chemical compound, and the controller 815 may be programed to, prior to the first operation, open the second valve 808 to the second source 804 to flow the first etchant into the reaction chamber 801, then close the second valve 808 to the second etchant. After the continuous etch operation, the controller 815 may be programed to repeatedly perform the first operation and the second operation (n times) or repeatedly perform the first operation, the second operation, and the third operation (n times) to remove a targeted thickness of the Mo outer layer from the substrate 811.

In some embodiments, a system for etching an Mo surface comprises: a reaction space for accommodating a substrate comprising an Mo outer layer having an initial thickness; a first source for providing an oxygen containing reactant in gas communication via a first valve with the reaction space; a second source for providing a first etchant in gas communication via a second valve with the reaction space; and a controller operably connected to the first valve and the second valve. The controller may be configured and programmed to perform a cyclic etch process by sequentially controlling: opening the first valve to the first source to supply the oxygen containing reactant into the reaction space, wherein the oxygen containing reactant converts at least a portion of the Mo outer layer to molybdenum oxide (MoOₓ); closing the first valve to the first source to cease the supply the oxygen containing reactant into the reaction space; opening the second valve to the second source to supply the first etchant into the reaction space, wherein the first etchant converts the MoOₓ to a volatile Mo containing compound; and closing the second valve to the second source to cease the supply of the first etchant into the reaction space. In some embodiments, the controller is further programed to sequentially repeat the opening of the first valve to the first source, the closing of the first valve to the first source, the opening of the second valve to the second source, and the closing of the second valve to the second source to reduce the initial thickness of the Mo outer layer to a final thickness or remove to the Mo outer layer from the substrate. In some embodiments, the system further comprises a third source for providing a second etchant in gas communication via a third valve with the reaction space and the controller is further operably connected to the third valve and configured and programmed to control: opening the third valve to the third source to supply the second etchant into the reaction space, wherein the second etchant removes a non-Mo oxide layer from the surface of the substrate; and closing the third valve to the third source to cease the supply of the second etchant into the reaction space. The controller may be further programed to, after each of the closing of the second valve to the second source, open the third valve to the third source and close the third valve to the third source.

In some embodiments, the system is further configured to provide a continuous etchant to the reaction space prior to performing the cyclic etch process. In some embodiments, the system is further configured to provide a continuous etchant to the reaction space prior to performing the cyclic etch process. In some of these embodiments, the continuous etchant and the first etchant are the same chemical compound and, prior to the opening of the first value to the first source, the controller is further programed to open the second valve to the second source and then close the second valve to the second source. In some other of these embodiments, the semiconductor apparatus further comprises a fourth source for providing a continuous etchant in gas communication via a fourth valve with the reaction space and the controller is further operably connected to the fourth valve and configured and programmed to control opening the fourth valve to the fourth source to supply the continuous etchant into the reaction space, wherein the continuous etchant reduces the initial thickness of the Mo outer layer to an intermediate thickness; and closing the fourth valve to the fourth source to cease the supply of the continuous etchant into the reaction space. Prior to the opening of the first value to the first source, the controller is further programed to open the fourth valve to the fourth source and then close the fourth valve to the fourth source.

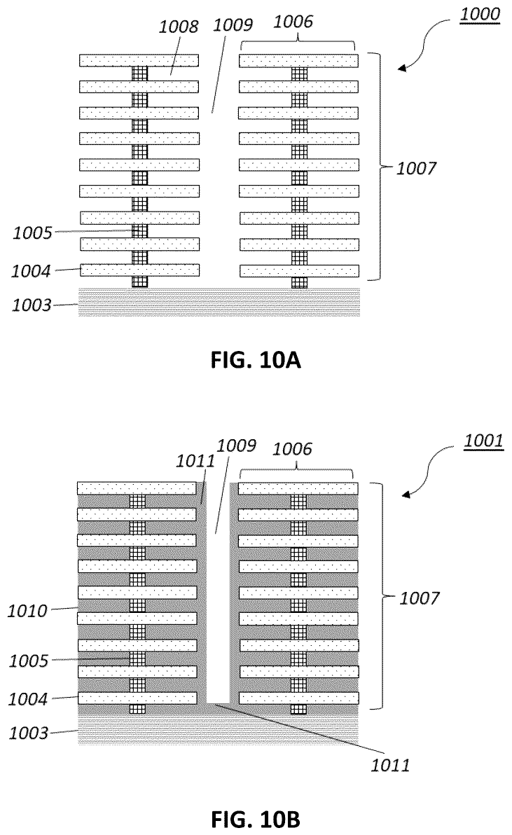

The methods and systems disclosed herein may be used in a variety of applications for semiconductor device manufacturing. For example, the methods and systems disclosed herein may be used to form local interconnects on a substrate surface. Interconnects may be formed by forming at least one trench or recessed feature on a surface of a substrate and then filling the at least one trench or recessed feature with a suitable metal (e.g., molybdenum). Other lining or barrier layers may optionally be deposited in the trench(es) or recessed feature(s) prior to filling the trench(es) or recessed feature(s) with the metal. Deposition of the metal within the trench(es) or the recessed feature(s) results in a metal outer layer or overburden (e.g., an Mo outer layer) on at least a portion of the lateral surface of the substrate. Removal of the metal outer layer is necessary for further substrate processing. An exemplary structure at various stages of fabrication is shown pictorially in FIG. 9A, FIG. 9B, and FIG. 9C. FIG. 9A shows a substrate 904 comprising a recessed feature 903, wherein the recessed feature is optionally lined with a liner or barrier material 905. FIG. 9B shows the substrate 904 after the recessed feature has been filled with molybdenum 906. An Mo outer layer 907 is present on the surface of the substrate over the now filled recessed feature. FIG. 9C shows the substrate 904 after the Mo outer layer has been removed. The substrate 904 comprises a filled recessed feature 906, wherein the filled recessed feature is optionally lined with a liner or barrier material 905 and filled with molybdenum 906. As will be appreciated by those skilled in the art, the methods and systems disclosed herein may be used to remove the Mo outer layer 907 from the structure shown in FIG. 9B to obtain the structure shown in FIG. 9C.

In another example, the methods and systems disclosed herein may be used for word line or, in more general, memory cell separation during the fabrication of 3D memory stack structures. Generally, memory line features in 3D memory stacks may be formed by depositing a plurality of alternating material layers and sacrificial layers on a substrate. At least one trench is then formed through the various material layers and sacrificial layers, forming at least two adjacent stacks and exposing vertical surfaces of the material layers and the sacrificial layers which make up the sidewalls of the trench(es). Next, at least a portion of each sacrificial layer is selectively removed leaving gaps between some or all of the material layers. The gaps are then filled with a metallic material (e.g., molybdenum) using a suitable deposition method (e.g., chemical vapor deposition or atomic layer deposition). The deposition process also results in the formation of a metal outer layer or overburden (e.g., an Mo outer layer) on the sidewalls and the bottom(s) of the trench(es) and, in some instances, the tops of the stacks, electrically connecting the various metallic layers. Removal of the metal outer layer separates the memory cell lines from one another.

An exemplary intermediate 3D NAND stacked structure is shown pictorially in FIG. 10A, FIG. 10B, and FIG. 10C at various stages of fabrication. FIG. 10A shows two intermediate 3D NAND stacks 1000 separated by a trench 1009, each stack comprising a plurality of stacked oxide layers 1004 on a substrate 1003 that are supported by a memory string 1005. Each stack comprises a top portion 1006 and sidewalls 1007 with a plurality of openings in the sidewalls due to gaps 1008 between the oxide layers 1004. A given stack may have between 2 and 256 gaps or more with more advanced devices having a larger number. FIG. 10B shows the two intermediate 3D NAND stacks 1001 after the gaps have been filled with a molybdenum 1010. During Mo deposition, an Mo outer layer 1011 is formed on the sidewalls 1007 and the bottom of the trench 1011, electrically connecting the individual molybdenum lines 1010 within the stacks. FIG. 10C shows the two intermediate 3D NAND stacks 1002 after the Mo outer layer has been removed, thereby separating the plurality of molybdenum lines 1010 from one another. As will be appreciated by those skilled in the art, the methods and systems disclosed herein may be used to remove the Mo outer layer 1011 from the intermediate 3D NAND stack structure 1001 shown in FIG. 10B, thereby separating the molybdenum lines 1010 from each other. More specifically, memory cell separation or line separation may be realized by providing a substrate comprising an intermediate 3D NAND stack structure comprising an Mo outer layer in a reaction space and removing the Mo outer layer using the methods and systems disclosed here. In some embodiments, the methods and systems disclosed herein are used to remove molybdenum from the sidewalls of an intermediate 3D NAND stack structure. In some embodiments, molybdenum removal occurs under thermal conditions (i.e., in a plasma free environment). In some embodiments, the substrate is maintained at a temperature of 450° C. or less, or at a temperature of 425° C. or less, or even at a temperature of 400° C. or less. Such conditions may beneficially allow for etching of molybdenum from the sidewalls of high aspect ratio recesses or trenches between two or more neighboring stacks.

An exemplary intermediate 3D DRAM stacked structure is shown pictorially in FIG. 11A, FIG. 11B, and FIG. 11C at various stages of fabrication. FIG. 11A shows two intermediate 3D DRAM stacks 1100 separated by a trench 1110, each stack comprising a plurality of alternating channel layers 1106 and insulating layers 1107 on a substrate 1104. Each stack may be divided into an inner stacked region 1111 and an outer stacked region 1112. The outer stacked region 1112 further comprises a plurality of sacrificial layers 1105 surrounding the outer portions of the channel layers 1106, each of which will be removed in subsequent manufacturing steps to form a plurality of capacitors. The inner stack region 1111 further comprises a plurality of gate oxide material layers 1109 surrounding the inner potions of the channel layers 1106 and a plurality of gaps 1108 between the inner portions of the channel layers 1106 and the insulating layers 1107. FIG. 11B shows the two intermediate 3D DRAM stacks 1101 after the plurality of gaps have been filled with molybdenum 1113. During Mo deposition, an Mo outer layer 1114 is formed on the sidewalls 1115 and the bottom of the trench 1116, electrically connecting the individual molybdenum lines 1113 within the stacks. FIG. 11C shows the two intermediate 3D DRAM stacks 1102 after the Mo outer layer has been removed, thereby separating the plurality of molybdenum lines 1113 from one another. As will be appreciated by those skilled in the art, the methods and systems disclosed herein may be used to remove the Mo outer layer 1114 from the intermediate 3D DRAM structure 1101 shown in FIG. 11B, thereby separating the molybdenum lines 1113 from each other. More specifically, memory cell separation or line separation may be realized by providing a substrate comprising an intermediate 3D DRAM stack structure comprising an Mo outer layer in a reaction space and removing the Mo outer layer using the methods and systems disclosed here. In some embodiments, the methods and systems disclosed herein are used to remove molybdenum from the sidewalls of an intermediate 3D DRAM stack structure. In some embodiments, molybdenum removal occurs under thermal conditions (i.e., in a plasma free environment). In some embodiments, the substrate is maintained at a temperature of 450° C. or less, or at a temperature of 425° C. or less, or even at a temperature of 400° C. or less. Such conditions may beneficially allow for etching of molybdenum from the sidewalls of high aspect ratio recesses or trenches between two or more neighboring stacks.

Although certain embodiments and examples are disclosed herein, it will be understood by those skilled in the art that the disclosed methods and systems extend beyond the specifically disclosed embodiments and include all novel and nonobvious combinations and sub-combinations of the various methods, systems, and configurations, as well as any and all equivalents thereof. It is to be understood that the methods and/or systems and/or structures described herein are exemplary in nature, and that these specific embodiments or examples are not to be considered in a limiting sense, because numerous variations are possible. The specific methods and systems described herein may represent one or more of any number of processing strategies. Thus, the various steps illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods, systems, and structures of the disclosure is not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiments of the disclosure.

1. A method for etching molybdenum (Mo) from a surface of a substrate, the method comprising:
providing a substrate comprising an Mo outer layer having an initial thickness in a reaction space; and
performing a cyclic etch process, comprising:
exposing the substrate to an oxygen containing reactant to convert at least a portion of the Mo outer layer to molybdenum oxide (MoOₓ);
purging the reaction space;
exposing the substrate to a first etchant to convert the MoOₓ to a volatile Mo containing compound, wherein the first etchant comprises one or more of S—X bond(s), P—X bond(s), and Si—X bond(s), wherein X is Cl or Br; and
purging the reaction space.

2. The method according to claim 1, further comprising: repeating the cyclic etch process to reduce the initial thickness of the Mo outer layer to a final thickness or to remove the Mo outer layer from the substrate.

3. The method according to claim 1, wherein the first etchant is selected from the group consisting of thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof.

4. The method according to claim 3, wherein the first etchant is selected from the group consisting of SOCl₂, PCl₃, PCl₅, and combinations thereof.

5. The method according to claim 1, wherein the cyclic etch process further comprises: exposing the substrate to a second etchant to remove a non-Mo oxide layer from the substrate.

6. The method according to claim 5, wherein the first etchant comprises SiCl₄ and the second etchant comprises HF.

7. The method according to claim 1, wherein the oxygen containing reactant is selected from the group consisting of oxygen (O₂), ozone (O₃), water (H₂O), hydrogen peroxide (H₂O₂), an organic peroxide, an alcohol, nitrogen dioxide (NO₂), nitrous oxide (N₂O), nitric oxide (NO), dinitrogen pentoxide (N₂O₅), pyridine oxide (C₅H₅NO), an amine oxide, and combinations thereof.

8. The method according to claim 1, wherein the oxygen containing reactant comprises one or more of O₂, O₃, and N₂O.

9. The method according to claim 1, wherein the cyclic etch process is performed under thermal conditions in a plasma-free environment.

10. The method according to claim 1, further comprising heating the substrate to a temperature of less than about 450° C.

11. The method according to claim 1, wherein X═Cl and the volatile Mo containing compound is a molybdenum oxychloride.

12. The method according to claim 1, further comprising performing a continuous etch step prior to the cyclic etch process, wherein the continuous etch step comprises exposing the substrate to a continuous etchant.

13. The method according to claim 12, wherein the continuous etchant is selected from the group consisting of molybdenum pentachloride (MoCl₅), thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof.

14. The method according to claim 12, wherein the first etchant and the continuous etchant are the same chemical compound, wherein the substrate is maintained at a first temperature during the continuous etch step and a second temperature during the cyclic etch process, wherein the first temperature is greater than the second temperature.

15. The method according to claim 1, wherein the substrate comprises at least one intermediate 3D NAND stacked structure or at least one intermediate 3D DRAM stacked structure, wherein the Mo outer layer is positioned on at least one sidewall of the at least one intermediate 3D NAND stacked structure or the at least one intermediate 3D DRAM stacked structure.

16. A method for etching a molybdenum containing film, the method comprising:
providing a substrate comprising a molybdenum containing film in a reaction space, wherein the molybdenum containing film comprises an outer layer positioned over a bulk region, wherein the outer layer comprise molybdenum oxide (MoOₓ) and the bulk region comprise metallic molybdenum; and
exposing the substrate to an etchant selected from the group consisting of thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof to convert at least a portion of the outer layer of the molybdenum containing film to a volatile Mo containing compound, thereby reducing a thickness of the molybdenum containing film.

17. The method of claim 16, wherein the etchant is selected from the group consisting of SOCl₂, PCl₃, PCl₅, SiCl₄, and combinations thereof.

18. A semiconductor processing apparatus, comprising:
a reaction space for accommodating a substrate comprising an Mo outer layer having an initial thickness;
a first source for providing an oxygen containing reactant in gas communication via a first valve with the reaction space;
a second source for providing a first etchant in gas communication via a second valve with the reaction space, wherein the first etchant comprises one or more of S—X bond(s), P—X bond(s), and Si—X bond(s), where X is Cl or Br; and
a controller operably connected to the first valve and the second valve, the controller configured and programmed to perform a cyclic etch process by sequentially controlling:
opening the first valve to the first source to supply the oxygen containing reactant into the reaction space, wherein the oxygen containing reactant converts at least a portion of the Mo outer layer to molybdenum oxide (MoOₓ);
closing the first valve to the first source to cease the supply the oxygen containing reactant into the reaction space;
opening the second valve to the second source to supply the first etchant into the reaction space, wherein the first etchant converts the MoOₓ to a volatile Mo containing compound; and
closing the second valve to the second source to cease the supply of the first etchant into the reaction space,
wherein the controller is further programed to sequentially repeat the opening of the first valve to the first source, the closing of the first valve to the first source, the opening of the second valve to the second source, and the closing of the second valve to the second source to reduce the initial thickness of the Mo outer layer to a final thickness or to remove the Mo outer layer from the substrate.

19. The semiconductor processing apparatus of claim 18, wherein the first etchant is selected from the group consisting of thionyl chloride (SOCl₂), sulfuryl chloride (SO₂Cl₂), disulfur dichloride (S₂Cl₂), thionyl bromide (SOBr₂), sulfuryl bromide (SO₂Br₂), disulfur dibromide (S₂Br₂), phosphorus pentachloride (PCl₅), phosphorus trichloride (PCl₃), phosphoryl chloride (POCl₃), phosphorus pentabromide (PBr₅), phosphorus tribromide (PBr₃), phosphoryl bromide (POBr₃), silicon tetrachloride (SiCl₄), trichlorosilane (SiHCl₃), dichlorosilane (SiH₂Cl₂), chlorosilane (SiH₃Cl), and hexachlorodisilane (Si₂Cl₆), silicon tetrabromide (SiBr₄), tribromosilane (SiHBr₃), dibromosilane (SiH₂Br₂), bromosilane (SiH₃Br), hexabromodisilane (Si₂Br₆), and combinations thereof.

20. The semiconductor processing apparatus of claim 19, wherein the first etchant is selected from the group consisting of SOCl₂, PCl₃, PCl₅, SiCl₄, and combinations thereof.
